(19) United States
(12) Patent Application Publication
(10) Pub. No.: US 2026/0371772 A1
(43) Pub. Date: Nov. 19, 2026

(54) SEMICONDUCTOR PACKAGE AND METHOD FOR FORMING THE SAME

(71) Applicant: STATS ChipPAC Pte. Ltd., Singapore (SG)

(72) Inventor: YiXiang Jasper TAY, Singapore (SG)

(21) Appl. No.: 19/676,748

(22) Filed: May 13, 2026

(30) Foreign Application Priority Data
May 15, 2025 (CN) 202510627470.9

(51) Int. Cl. H10F 39/95; G02B 6/13; H10W 70/09; H10W 74/01; H10W 74/10

(52) U.S. Cl. CPC H10F 39/95; G02B 6/13; H10W 70/09; H10W 74/01; H10W 74/131

(57) ABSTRACT

A semiconductor package and a method for forming the same are provided. The method includes: providing a sub-package including a first electronic component; a first encapsulant encapsulating the first electronic component; an interconnection layer formed on an upper surface of the first encapsulant; a second electronic component mounted on an upper surface of the interconnection layer; and a cavity formed in the interconnection layer and the first encapsulant to expose a coupling region of the first electronic component; disposing a molding component in the cavity to cover the coupling region; and forming an underfill layer on the upper surface of the interconnection layer to fill a gap between the second electronic component and the interconnection layer and hold the molding component within the cavity.

### TECHNICAL FIELD

The present application generally relates to semiconductor technology, and more particularly, to a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, an integrated passive device (IPD), a RF filter, a sensor, a heat sink, or an antenna. Recently, photonic devices, which are capable of transmitting or receiving signals via light, are becoming more and more common. However, the options for packaging photonic devices into SiP have heretofore been limited and unsatisfactory in many ways. For example, adhesives may be used to attach fiber array units with the photonic devices. However, the use of adhesives may introduce contaminants into the semiconductor package, resulting in low reliability.

Therefore, a need exists for a semiconductor package with improved reliability.

### SUMMARY OF THE INVENTION

An objective of the present application is to provide a method for forming a semiconductor package with improved reliability.

According to an aspect of the present application, a method for forming a semiconductor package is provided. The method may include: providing a sub-package including a first electronic component; a first encapsulant encapsulating the first electronic component; an interconnection layer formed on an upper surface of the first encapsulant; a second electronic component mounted on an upper surface of the interconnection layer; and a cavity formed in the interconnection layer and the first encapsulant to expose a coupling region of the first electronic component; disposing a molding component in the cavity to cover the coupling region; and forming an underfill layer on the upper surface of the interconnection layer to fill a gap between the second electronic component and the interconnection layer and hold the molding component within the cavity.

According to another aspect of the present application, a semiconductor package is provided. The semiconductor package may include: a first electronic component having a coupling region at its upper surface; a first encapsulant encapsulating the first electronic component; an interconnection layer formed on an upper surface of the first encapsulant; a second electronic component mounted on an upper surface of the interconnection layer; a cavity formed in the interconnection layer and the first encapsulant to expose the coupling region of the first electronic component; a protective ring formed in the cavity and surrounding the coupling region of the first electronic component; and an underfill layer formed on the upper surface of the interconnection layer, wherein the underfill layer fills a gap between the second electronic component and the interconnection layer and holds the protective ring within the cavity.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A-1G are cross-sectional and bottom views illustrating various steps of a method for forming a semiconductor package according to an embodiment of the present application.

FIG. 2 is a cross-sectional view of a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

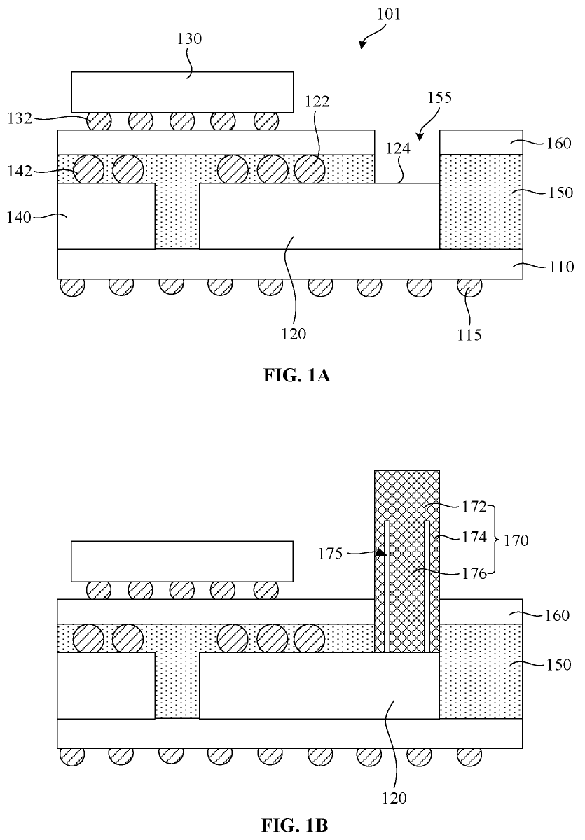

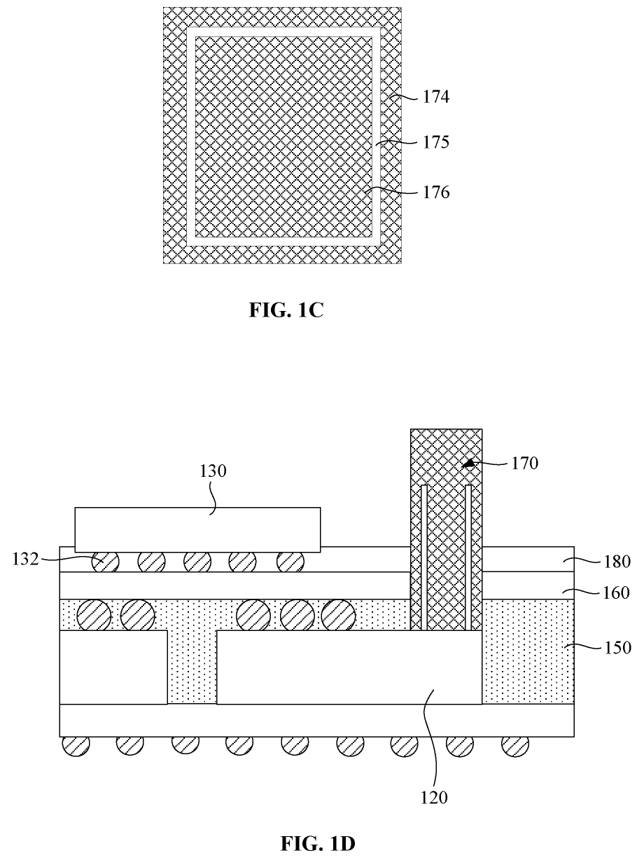

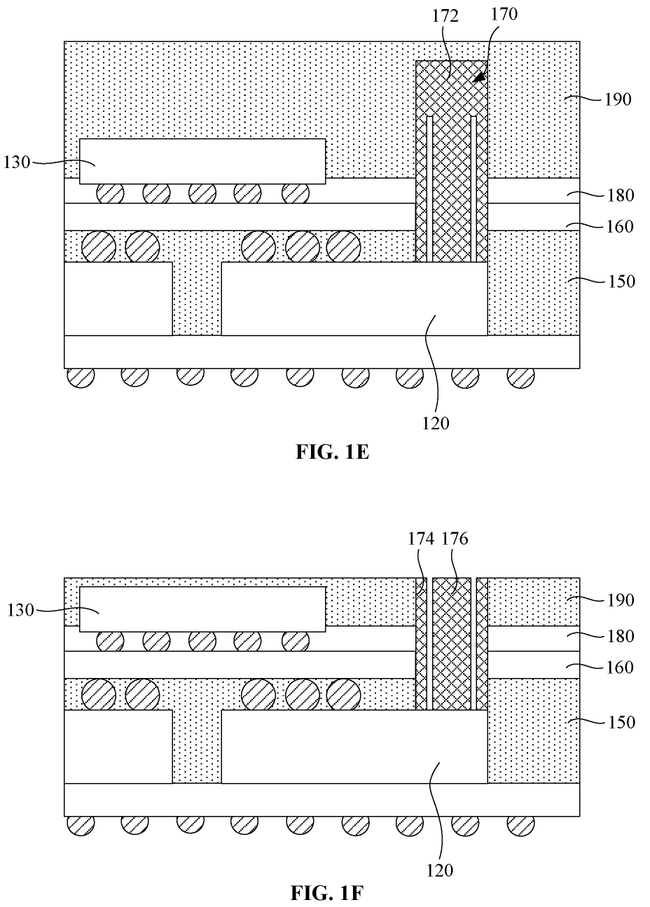

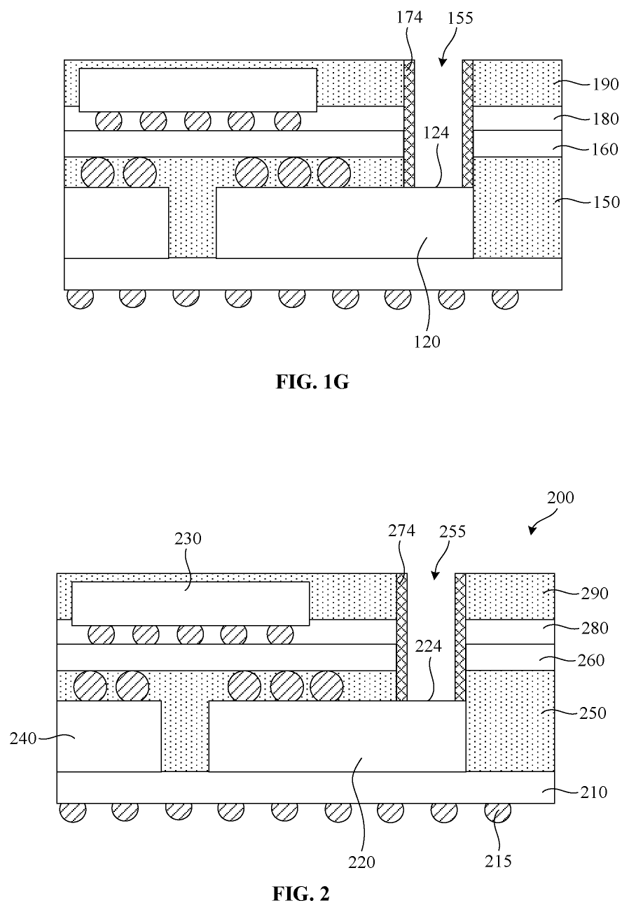

Referring to FIGS. 1A-1G, cross-sectional and bottom views illustrating various steps of a method for forming a semiconductor package are illustrated according to an embodiment of the present application. In the following, the method will be described with reference to FIGS. 1A-1G in more details.

Referring to FIG. 1A, a sub-package 101 is provided. The sub-package 101 may include a substrate 110, and a first electronic component 120 attached on an upper surface of the substrate 110. A first encapsulant 150 is formed on the upper surface of the substrate 110 to encapsulate the first electronic component 120, and an interconnection layer 160 is formed on an upper surface of the first encapsulant 150. Further, a second electronic component 130 is mounted on an upper surface of the interconnection layer 160, and a cavity 155 is formed in the interconnection layer 160 and the first encapsulant 150 to expose a coupling region 124 of the first electronic component 120.

The substrate 110 can support the electronic components mounted thereon and further electrically connect the electronic components with other electronic components. By way of example, the substrate 110 may be a printed circuit board. However, the substrate 110 is not limited thereto. In other examples, the substrate 110 may be a semiconductor substrate, a laminate interposer, a strip interposer, a leadframe, or other suitable substrates. In accordance with the scope of the present application, the substrate 110 may include any structure on or in which integrated circuit systems are fabricated. For example, the substrate 110 may include one or more insulating or passivation layers, one or more conductive vias formed through the insulating layers, and one or more conductive layers formed over or between the insulating layers. For example, redistribution structures may be formed in the substrate 110, which include a plurality of upper conductive patterns on the upper surface of the substrate 110, a plurality of lower conductive patterns on the lower surface of the substrate 110, and/or a plurality of conductive vias electrically connecting at least one of the upper conductive patterns with at least one of the lower conductive patterns.

In some embodiments, the first electronic component 120 and/or the second electronic component 130 may include one or more digital chips, analog chips or mixed signal chips, such as application-specific integrated circuit chips, sensor chips, wireless and radio frequency chips, memory chips, logic chips or voltage regulator chips. The first electronic component 120 and/or the second electronic component 130 may be manufactured using a surface fabrication process or other similar processes. That is, various types of analog or digital circuits, which may be implemented as active devices and/or passive devices, may be formed close to their active surfaces.

By way of example, the first electronic component 120 may include a photonic component. The photonic component may be a photonic integrated circuit (PIC), which has the capability to transmit and/or receive light signals. The PIC may be fabricated on a substrate of silicon, silica, or a nonlinear crystal material such as lithium niobate. For example, the PIC may include optical components such as waveguides, lasers, polarizers, and phase shifters, and can be used in areas such as optical fiber communications, optical metrology, quantum computing etc. Accordingly, the coupling region 124 of the first electronic component 120 may be an optical coupling region, which is used to optically couple with fiber optic structures such as a fiber array unit (FAU). The fiber array unit can carry light signals to and/or from the photonic component.

However, the present application is not limited to the above example. In other examples, the first electronic component 120 may need to transmit electrical signals to, and/or receive electrical signals from other electronic components. The coupling region 124 of the first electronic component 120 may be used to electrically couple with conductive structures such as a copper post, so as to carry electrical signals to and/or from the photonic component.

The coupling region 124 of the first electronic component 120 is exposed by the cavity 155 formed in the interconnection layer 160 and the first encapsulant 150, and needs to be kept clean in subsequent processes to facilitate the installation of a coupling component (for example, the FAU). The cavity 155 may have a vertical or sloping lateral surface. In some embodiments, the first encapsulant 150 may be made of a polymer composite material, such as epoxy resin with filler, epoxy acrylate with filler, or other polymers with proper filler, but the scope of this application is not limited thereto. The first encapsulant 150 can provide mechanical protection, environmental protection, and a hermetic seal for electronic components and structures in the sub-package 101.

In some embodiments, the interconnection layer 160 may be a redistribution layer. The redistribution layer may include one or more dielectric layers and one or more conductive layers between and through dielectric layers. The conductive layers may define pads, traces and plugs through which electrical signals or voltages can be distributed horizontally and vertically across the redistribution layer. For example, the conductive layers may form a plurality of contact pads on the upper surface of the interconnection layer 160 and also form a plurality of contact pads on the lower surface of the interconnection layer 160. Accordingly, as shown in FIG. 1A, a plurality of conductive bumps (for example, solder balls) 122 formed on the upper surface of the first electronic component 120 may be used to electrically couple the first electronic component 120 to the contact pads formed on the lower surface of the interconnection layer 160, and a plurality of conductive bumps 132 formed on the lower surface of the second electronic component 130 may be used to electrically couple the second electronic component 130 to the contact pads formed on the upper surface of the interconnection layer 160. It could be understood that the interconnection layer 160 may be implemented in various structures and types, and aspects of the present application are not limited thereto. In some other examples, the interconnection layer 160 may be a silicon-based interposer and can offer various advantages. For example, the interposer can support fine pitches for through-silicon vias (TSVs) and traces used in signal and power distribution, and may have a thermal expansion coefficient which can match that of the first electronic component 120 and the second electronic component 130.

In some embodiments, at least one third electronic component 140 is also attached on the upper surface of the substrate 110. The third electronic component 140 may include any of a variety of types of semiconductor dice, semiconductor packages, or discrete devices. The third electronic component 140 may be laterally adjacent to the first electronic component 120. In some embodiments, a thickness of the third electronic component 140 is substantially the same as that of the first electronic component 120, and both the third electronic component 140 and the first electronic component 120 are flip chip bonded to the lower surface of the interconnection layer 160. For example, as shown in FIG. 1A, a plurality of conductive bumps 142 may be formed on the upper surface of the third electronic component 140 to couple with the contact pads formed on the lower surface of the interconnection layer 160, such that the third electronic component 140 and the first electronic component 120 can be electrically connected with each other via the interconnection layer 160.

In some embodiments, as shown in FIG. 1A, a plurality of conductive bumps 115 may be formed on the lower surface of the substrate 110 and electrically coupled with the first electronic component 120, the second electronic component 130 and/or the third electronic component 140 via the substrate 110 and/or the interconnection layer 160. In the example shown in FIG. 1A, the plurality of conductive bumps 115 are illustrated as solder bumps, but the present application is not limited thereto. In some other embodiments, the plurality of conductive bumps 115 may include copper posts, or any other suitable metallic bumps. In a case where the semiconductor package is mounted on an external device or substrate such as a printed circuit board (PCB), the plurality of conductive bumps 115 may be used for electrically connecting the semiconductor package to the external device or substrate.

While the sub-package 101 is described with reference to FIG. 1A, it will be understood by those skilled in the art that the configuration of the sub-package 101 is exemplary and not mandatory, and modifications and adaptations to the sub-package 101 may be made without departing from the scope of the present invention.

Referring to both FIGS. 1A and 1B, a molding component 170 is disposed in the cavity 155 to cover the coupling region 155 of the first electronic component 120.

As described above, the coupling region 124 of the first electronic component 120 is exposed by the cavity 155 formed in the interconnection layer 160 and the first encapsulant 150, and needs to be kept clean in subsequent processes. The molding component 170 is a sacrificial or dummy component to keep the coupling region 124 clear during subsequent molding or grinding processes. The molding component 170 may be pre-formed, and have a size that is essentially the same as, or slightly smaller than, the cavity 155 formed in the interconnection layer 160 and the first encapsulant 150. The molding component 170 may be formed by a molding process or any other suitable process and include a molding material such as epoxy resin, epoxy acrylate resin, or polymer with proper filler, but the scope of this application is not limited thereto.

In some embodiments, as shown in FIG. 1B, the molding component 170 may include a cap portion 172, a lateral portion 174 and a central portion 176. A projection of the cap portion 172 onto the upper surface of the first electronic component 120 overlaps with the coupling region 124, and preferably covers the entirety of the coupling region 124, and thus the molding component 170 can protect the coupling region 124 during subsequent processes. The cap portion 172 of the molding component 170 protrudes above the upper surface of the second electronic component 130, thereby facilitating the removal of the cap portion 172 in subsequent steps. The lateral portion 174 extends downward from a peripheral region of the cap portion 172 and may form a recess within the molding component 170 together with the cap portion 172. The central portion 176 may be formed in the recess and extend downward from a central region of the cap portion 172. The central portion 176 can improve the mechanical strength of the molding component 170 and further protect the coupling region 124. In some examples, a lower surface of central portion 176 may be coplanar with a lower surface of the lateral portion 174. However, the scope of the present application is not limited to this configuration. In other examples, the lower surface of central portion 176 may be higher than the lower surface of the lateral portion 174. The central portion 176 and the lateral portion 174 are separated from each other. Specifically, as shown in FIG. 1B, a gap 175 exists between the central portion 176 and the lateral portion 174. Thus, in subsequent processes, after the cap portion 172 is removed, the central portion 176 can also be removed, while the lateral portion 174 can be retained. This will be described in detail below.

Referring to FIG. 1C, a bottom view of the molding component 170 shown in FIG. 1B is illustrated according to an example of the present application. As shown in FIG. 1C, the lateral portion 174 of the molding component 170 may form a closed ring, with the central portion 176 being a rectangle located within the closed ring. It will be understood by those skilled in the art that the configuration of the molding component shown in FIG. 1B and 1C is exemplary, and modifications and adaptations to the molding component may be made without departing from the scope of the present invention. For example, in some embodiments, the lateral portion and the central portion may have a circular, octagonal, or irregular shape. In other embodiments, the central portion may be omitted, and the molding component may only include the cap portion and the lateral portion.

Referring to FIG. 1D, an underfill layer 180 is formed on the upper surface of the interconnection layer 160 to fill a gap between the second electronic component 130 and the interconnection layer 160 and hold the molding component 170 within the cavity 155.

As shown in FIG. 1D, the underfill layer 180 is formed between the second electronic component 130 and the interconnection layer 160 to encapsulate the conductive bumps 132 therebetween, and optionally cover lateral surfaces of the second electronic component 130. Further, the underfill layer 180 may surround the molding component 170 to hold the molding component 170 within the cavity 155. The underfill layer 180 may include a non-conductive paste (NCP), a molded underfill (MUF), a non-conductive film (NCF), an underfill encapsulant, or a polymer composite material, such as epoxy resin, epoxy acrylate, or polymer with or without a filler. The underfill layer 180 may provide mechanical support to the second electronic component 130 and the molding component 170, helping to mitigate the risk of detachment or crack. In some embodiments, a fluid material is dispensed on the upper surface of the interconnection layer 160, allowing capillary action to draw the fluid material into the space between the second electronic component 130 and the interconnection layer 160 and around the molding component 170. Then the fluid material may be cured to form the underfill layer 180. In some cases, when a gap exists between the molding component 170 and the interconnection layer 160 and first encapsulant 150, the fluid material may flow into the gap and the underfill layer 180 is also formed therein. However, the present application is not limited thereto. In other cases, the underfill layer 180 is only formed on the upper surface of the interconnection layer 160.

Compared to a solution that uses an adhesive to attach the molding component 170 onto the coupling region 124, using the underfill layer 180 to hold the molding component 170 within the cavity 155 can reduce contaminants of the coupling region 124. Further, the underfill layer 180 can be formed by a baseline process needed for flip-chip attachment, saving cycle time and eliminating the need for new tools and materials for dispensing adhesive.

Referring to FIG. 1E, a second encapsulant 190 is formed on the underfill layer 180 to encapsulate the second electronic component 130 and the molding component 170.

In some embodiments, a molding process is performed on the entire upper surface of the underfill layer 180 to form the second encapsulant 190. The second encapsulant 190 may cover the lateral and upper surfaces of the second electronic component 130, and the lateral and upper surfaces of the molding component 170. The second encapsulant 190 may include a polymer composite material, such as epoxy resin, epoxy resin with filler, epoxy acrylate with filler, or other polymers with proper filler, but the scope of this application is not limited thereto. The second encapsulant 190 may be formed using a molding process such as an injection molding process. However, the present application is not limited thereto. In some other embodiments, the second encapsulant 190 may be formed using various other molding techniques, including a transfer molding process, a compression molding process, a film-assisted molding process, etc.

Referring to both FIGS. 1E and 1F, the second encapsulant 190 is grinded to remove the cap portion 172 of the molding component 170.

In some embodiments, a grinder may be used to perform the grinding process. As the grinding process can planarize a top surface of the entire package, an upper portion of the second encapsulant 190 and the cap portion 172 of the molding component 170 may be removed simultaneously to ensure the upper surface of second encapsulant 190 and the upper surface of the molding component 170 (i.e., upper surfaces of the lateral portion 174 and the central portion 176) can be substantially flush or coplanar with each other.

In the example shown in FIG. 1F, as the cap portion 172 of the molding component 170 is higher than the upper surface of the second electronic component 130, the upper surface of the second electronic component 130 is still covered by the second encapsulant 190 after the grinding process. However, the present application is not limited thereto. In other examples, an upper portion of the second electronic component 130 may be grinded to reduce its thickness.

As shown in FIG. 1B, the lateral portion 174 and the central portion 176 of the molding component 170 extend downward from the cap portion 172 and are separated from each other. Thus, as shown in FIG. 1F, after the cap portion 172 of the molding component 170 is removed, the lateral portion 174 is held within the cavity by the underfill layer 180 and the second encapsulant 190, while the central portion 176 is separated from other components of the semiconductor package and rests at the bottom of the cavity 155.

Referring to FIGS. 1F and 1G, because the central portion 176 is separated from other components of the semiconductor package, it can be removed from the cavity 155 to expose the coupling region 124 of the first electronic component 120. After removing the central portion 176, only the lateral portion 174 of the molding component 170 is retained in the cavity 155 by the underfill layer 180 and the second encapsulant 190 to serve as a protective ring of the coupling region 124.

In some embodiments, a fiber optic structure (for example, FAU) may be disposed in the cavity 155 to optically couple with the coupling region 124 of the first electronic component 120, thereby facilitating the transmission of light signals to and/or from the first electronic component 120. In some embodiments, a conductive structure (for example, copper post) may be disposed in the cavity 155 to electrically couple with the coupling region 124 of the first electronic component 120.

According to another aspect of the present application, a semiconductor package is provided. Referring to FIG. 2, a cross-sectional view of a semiconductor package 200 is illustrated according to an embodiment of the present application.

As shown in FIG. 2, the semiconductor package 200 may include a substrate 210, and a first electronic component 220 attached on an upper surface of the substrate 210. The first electronic component 220 may have a coupling region 224 at its upper surface. A first encapsulant 250 is formed on the upper surface of the substrate 210 to encapsulate the first electronic component 220, and an interconnection layer 260 is formed on an upper surface of the first encapsulant 250. A second electronic component 230 is mounted on an upper surface of the interconnection layer 260, and a cavity 255 is formed in the interconnection layer 260 and the first encapsulant 250 to expose the coupling region 224 of the first electronic component 220. In addition, a protective ring 274 is formed in the cavity 255 and surrounds the coupling region 224 of the first electronic component 220. An underfill layer 280 is formed on the upper surface of the interconnection layer 260. The underfill layer 280 fills a gap between the second electronic component 230 and the interconnection layer 260 and holds the protective ring 274 within the cavity 255.

In some embodiments, the semiconductor package 200 may further include a second encapsulant 290. The second encapsulant 290 is formed on the underfill layer 280 to encapsulate the second electronic component 230 and to surround the protective ring 274.

In some embodiments, the first electronic component 220 may include a photonic component. A fiber array unit (not shown) may be disposed within the cavity 255 to optically couple with the photonic component through the coupling region 224.

In some embodiments, the semiconductor package 200 may further include a third electronic component 240. The first electronic component 220 and the third electronic component 240 are attached on the upper surface of the substrate 210 and are electrically coupled to the interconnection layer 260. A plurality of conductive bumps 215 may be formed on the lower surface of the substrate 210.

The semiconductor package 200 may be formed by the method described above with reference to FIGS. 1A-1G. For example, the protective ring 274 may be formed by the lateral portion 174 of the molding component 170 shown in FIG. 1B. More details about the semiconductor package 200 may be referred to the disclosure and drawings about the method disclosed above and will not be elaborated herein.

While the exemplary semiconductor package and the method for forming the semiconductor package of the present application are described in conjunction with corresponding figures, it will be understood by those skilled in the art that modifications and adaptations to the semiconductor package and the method may be made without departing from the scope of the present invention. The discussion herein included numerous illustrative figures that showed various portions of a semiconductor package and a method for making the same. For illustrative clarity, such figures did not show all aspects of each exemplary semiconductor package. Any of the example packages and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a sub-package comprising:
a first electronic component;
a first encapsulant encapsulating the first electronic component;
an interconnection layer formed on an upper surface of the first encapsulant;
a second electronic component mounted on an upper surface of the interconnection layer; and
a cavity formed in the interconnection layer and the first encapsulant to expose a coupling region of the first electronic component;
disposing a molding component in the cavity to cover the coupling region; and
forming an underfill layer on the upper surface of the interconnection layer to fill a gap between the second electronic component and the interconnection layer and hold the molding component within the cavity.

2. The method of claim 1, further comprising:
forming a second encapsulant on the underfill layer to encapsulate the second electronic component and the molding component.

3. The method of claim 2, wherein the molding component comprises:
a cap portion, wherein the cap portion is higher than an upper surface of the second electronic component; and
a lateral portion extending downward from a peripheral region of the cap portion, wherein the cap portion and the lateral portion together form a recess within the molding component.

4. The method of claim 3, further comprising:
grinding the second encapsulant to remove the cap portion of the molding component.

5. The method of claim 4, wherein the molding component further comprises:
a central portion extending downward from a central region of the cap portion and surrounded by the lateral portion, wherein the central portion and the lateral portion are separated from each other.

6. The method of claim 5, further comprising:
removing the central portion of the molding component from the cavity.

7. The method of claim 1, wherein the first electronic component comprises a photonic component.

8. The method of claim 7, further comprising:
disposing a fiber array unit (FAU) within the cavity to optically couple with the photonic component through the coupling region.

9. The method of claim 1, wherein the sub-package further comprises:
a substrate;
a third electronic component, wherein the first electronic component and the third electronic component are attached on an upper surface of the substrate and are electrically coupled to the interconnection layer; and
a plurality of conductive bumps formed on a lower surface of the substrate.

10. A semiconductor package, comprising:
a first electronic component having a coupling region at its upper surface;
a first encapsulant encapsulating the first electronic component;
an interconnection layer formed on an upper surface of the first encapsulant;
a second electronic component mounted on an upper surface of the interconnection layer;
a cavity formed in the interconnection layer and the first encapsulant to expose the coupling region of the first electronic component;
a protective ring formed in the cavity and surrounding the coupling region of the first electronic component; and
an underfill layer formed on the upper surface of the interconnection layer, wherein the underfill layer fills a gap between the second electronic component and the interconnection layer and holds the protective ring within the cavity.

11. The semiconductor package of claim 10, further comprising:
a second encapsulant formed on the underfill layer to encapsulate the second electronic component and to surround the protective ring.

12. The semiconductor package of claim 10, wherein the first electronic component comprises a photonic component.

13. The semiconductor package of claim 12, further comprising:
a fiber array unit (FAU) disposed within the cavity to optically couple with the photonic component through the coupling region.

14. The semiconductor package of claim 10, further comprising:
a substrate;
a third electronic component, wherein the first electronic component and the third electronic component are attached on an upper surface of the substrate and are electrically coupled to the interconnection layer; and
a plurality of conductive bumps formed on a lower surface of the substrate.
